(19) United States
(12) Patent Application Publication
(10) Pub. No.: US 2023/0160557 A1
(43) Pub. Date: May 25, 2023

(54) MINIMIZATION OF STOKES' LOSSES DUE TO PHOTON MULTIPLICATION PROCESSES FOR IR APPLICATIONS

(71) Applicant: OSRAM Opto Semiconductors GmbH, Regensburg (DE)

(72) Inventors: Ion STOLL, Tegernheim (DE); Marcus BOEHM, Thalmassing (DE)

(21) Appl. No.: 17/287,896

(22) PCT Filed: Oct. 22, 2019
(86) PCT No.: PCT/EP2019/078755

§ 371 Date: Sep. 8, 2021

(30) Foreign Application Priority Data
Oct. 23, 2018 (DE) 10 2018 126 355.4

(51) Int. Cl. F21V 9/32; C09K 11/02

(52) U.S. Cl. CPC F21V 9/32; C09K 11/02; B82Y 20/00

(57) ABSTRACT

The invention relates to a light-emitting component, comprising: at least one conversion element comprising: at least one first material selected from the group consisting of polyazene, rubrene and derivatives thereof; at least one second material, the second material being a quantum dot, and at least one light source, the at least one light source emitting at least one photon in the range of 3.5 eV to 2.5 eV, preferably in the range of 3.0 eV to 2.55 eV. The invention further relates to the use of a light-emitting component according to the invention.

### DESCRIPTION

Stokes heat generated during the conversion process of blue light to longer wavelength light in light emitting devices is a significant energy loss path. Conventional phosphors are not able to minimize those Stokes losses.

Current light-emitting devices provide no approach to reducing Stokes losses beyond the physical limit (i.e., the energy difference between the pump photon and the converted photon). To date, infrared (IR) light sources have been generated, for example, by InGaAs semiconductors directly or by blue LEDs using a phosphor by conversion (indirectly). In this context, low direct light quantum efficiencies of the phosphors or the temperature-dependent chips pose a problem.

The principle of combining a singlet fission material with inorganic IR quantum dots in a hybrid matrix to minimize losses within solar cells is described, for example, in US2014/0224329 A1.

It is an object of the present invention to provide a light emitting device. It is another object of the present invention to provide a use of a light emitting device according to the present invention.

These objects will be solved by a light-emitting component having the features of claim 1 and by a use according to claim 9.

Advantageous embodiments and further developments of the light-emitting component are set forth in the respective dependent claims.

The object of the present invention is to provide a light-emitting component comprising:
at least one conversion element comprising:
   at least one first material selected from the group consisting of polyacene, rubrene, and derivatives thereof;
   at least one second material, wherein the second material is a quantum dot; and
   at least one light source, wherein the at least one light source emits at least one photon in the range of 3.5 eV to 2.5 eV, preferably in the range of 3.0 eV to 2.55 eV.

A light emitting device may, for example, be a light emitting diode (LED).

In the context of the present invention, a conversion element is a component which is used to convert light having a specific first wavelength (primary radiation), completely or partially, into light of at least one second wavelength (secondary radiation).

The at least one conversion element comprises at least one first material selected from the group consisting of polyacene, rubrene and derivatives thereof.

The at least one light source of the light emitting device emits light (i.e., photons) of a specific wavelength. The energy of the photon in this case is in the range of 3.5 eV-2.5 eV, preferably in the range of 3-2.55 eV on average, e.g. 2.75 eV.

The first material of the conversion element is to absorb a photon from the light source. The absorption of the photon produces a singlet exciton. Singlet fission generates two triplet excitons from the singlet exciton.

Potential material systems for efficient singlet fission processes, and thus the first material, include polyacenes (especially tetracene and pentacene) and derivatives thereof, and specifically compounds having TIPS functionality (i.e., 6,13-bistriisopropylsilylethynyl), and rubrene.

The second material is in physical contact with the first material and is capable of receiving the generated triplet excitons from the at least one first material through energy transfer processes and re-emitting them as radiating photons.

The material combination of the at least one first material and the at least one second material is able to convert one high energy photon into two low energy photons during the conversion process. This is particularly preferable for generating two infrared photons (>900 nm; <1.375 eV) from one blue photon (450 nm; 2.75 eV). This allows generation of particularly efficient semiconductor-pumped conversion light sources emitting >900 nm.

For the overall conversion efficiency of the conversion element, the following individual efficiencies are substantially essential:
1. absorption efficiency of the first material
2. singlet fission rate of the first material
3. energy transfer efficiency and
4. photoluminescence quantum efficiency of the second material.

In singlet fission, a high-energy photon is absorbed in a so-called singlet fission matrix and converted into an exciton having effective orbital angular momentum 0 (i.e., singlet exciton). Due to favorable constellation of singlet and triplet energy levels in some organic materials, this singlet exciton is converted extremely rapidly (<a few ps; material dependent) into two excitons having effective orbital angular momentum 1 (i.e., 2 triplet excitons). As the final triplet initially performs as a “biexciton” thus having a global effective orbital angular momentum 0, no selection rule is violated, which may result in very fast singlet fission rates.

As a result of a low PLQE (photoluminescence quantum efficiency) of the triplets formed, a singlet fission matrix alone is not sufficient to initiate an efficient photon multiplication process. In the second material, this is accomplished by transferring the triplets into, for example, inorganic quantum dots through a non-radiative energy transfer process (i.e., Dexter Transfer). The strong spin-orbit interaction, caused by the heavier elements in the quantum dot, causes efficient mixing of singlet and triplet states. This favors radiative recombination of the excitons, which may raise the PLQE of the material combination of the at least one first material and the at least one second material above 100%.

This material combination of the at least one first material and the at least one second material is preferably placed into a conversion element in the light path of a light source (especially preferably a semiconductor-based light source such as an LED chip or laser).

In the context of the invention, the light path means the volume in which a photon can reside following generation before leaving the light source. E.g., the volume of an LED package.

According to the present invention, the second material is a quantum dot.

Materials that can spectrally be set to the infrared range through the so-called quantum confinement effect are especially suitable for the quantum dots. Among others, lead chalcogenides (e.g. PbS), mercury chalcogenides (e.g. HgSe, HgTe) or CuInS or CuInSe (the latter preferably having a ZnS shell) may be used. Other materials (e.g., semiconductor materials) for the quantum dots may include CdS, CdSe, CdTe, ZnS, ZnSe, ZnTe, HgTe, HgSe, GaP, GaAs, GaSb, AlP, AlAs, AlSb, InP, InAs, InSb, GaSb, SiC, InN, AlN, GaN, BN, ZnO, MgO, InSnO₂, SnO₂, or solid solutions thereof (ternary, quaternary, etc.) or a combination of several different materials (e.g., semiconductor materials).

Preferably, the embedded material of the quantum dot has a band gap in the range of 650 nm to 2 μm. Especially preferably, the embedded material of the quantum dot has a band gap in the range of 900 nm to 2 μm.

Core-shell architectures may also be used as the material for the quantum dots. The band gap energy difference between the core material and the shell material is, for example, 0.5 eV. Herein, the band gap of the shell material is preferably larger than that of the core material. The shell material may be e.g. CdS, CdSe, CdTe, ZnS, ZnSe, Zn Te, HgTe, HgSe, GaP, GaAs, GaSb, AlP, AlAs, AlSb, InP, InAs, InSb, SiC, InN, AlN or mixed crystals thereof (ternary, quaternary, etc.) or a combination of several different materials.

Instead of 3-dimensional confined quantum dots (quasi 0-dimensional quantum dots), 1-dimensional and 2-dimensional structures (i.e. nanowires or platelets) may also be used.

In one embodiment, the at least one quantum dot comprises one or more materials selected from the group consisting of PbS, HgSe, HgTe, CuInS, CuInSe, CdS, CdSe, CdTe, ZnS, ZnSe, ZnTe, HgTe, HgSe, GaP, GaAs, GaSb, AlP, AlAs, AlSb, InP, InAs, InSb, GaSb, SiC, InN, AlN, GaN, BN, ZnO, MgO, InSnO₂, SnO₂, or combinations thereof.

The light emitting device of the present invention may further comprise at least one phosphor.

In another embodiment, the light emitting device comprises at least one phosphor, preferably at least one phosphor selected from the group consisting of Cr³⁺-, Sm³⁺—, Yb³⁺-, Nd³⁺-, Bi²⁺-, Dy³⁺-, Ho³⁺-, Cr⁴⁺-, Ni²⁺-, Er³⁺-, Tm³⁺-, Ce³⁺-, Eu²⁺-, Yb²⁺-doped phosphors, organic phosphors, and organic hybrid phosphors, and combinations thereof.

In one embodiment, other luminescent materials, in addition to the conversion element, may be used to convert light of a first wavelength (preferably blue light). These materials may also be located in the conversion element or may be introduced downstream or upstream of the conversion element in the light path. They are preferably Cr³⁺-doped phosphors but also Sm³⁺-, Yb³⁺-, Nd³⁺-, Bi²⁺-, Dy³⁺-, Ho³⁺-, Cr⁴⁺, Ni²⁺-, Er³⁺-, Tm³⁺-doped phosphors or phosphors comprising combinations of the above-mentioned activators optionally comprising additional Ce³⁺, Eu²⁺, Yb²⁺.

According to a preferred embodiment, the other phosphor is selected from the group of the following phosphors consisting of:
Ce³⁺ garnets, for example:
   Y₃(Al₁₋ₓGaₓ)₅O₁₂:Ce³⁺,
   (Gd,Y)₃(Al₁₋ₓGaₓ)5O₁₂:Ce³⁺,
   (Tb,Y)₃(Al₁₋ₓGaₓ)₅O₁₂:Ce³⁺,
   Lu₃(Al₁₋ₓGaₓ)₅O₁₂:Ce³⁺,
   (Lu,Y)₃(Al₁₋ₓGaₓ)₅O₁₂:Ce³⁺,
Ce³⁺-doped (oxy)nitrides, for example:
   (La,Y)₃Si₆N₁₁:Ce³⁺,
   (La₁₋ₓCaₓ)₃Si₆(N_{1-y}O_{y})₁₁:Ce³⁺,
   Eu²⁺ oxides, (oxy)nitrides, for example:
   (Na,Li,K,Rb,Cs)[Li₃SiO₄]:Eu²⁺,
   (Ca,Sr)AlSiN₃:Eu²⁺,
   Sr(Sr,Ca)Si₂Al₂N₆:Eu²⁺,
   (Ca,Ba,Sr)₂Si₅N₈:Eu²⁺,
   SrAlSi₇N₄:Eu²⁺,
   Sr[Al₃LiN₄]:Eu²⁺,
   Ca[Al₃LiN₄]:Eu²⁺,
   Sr[Li₂Al₂O₂N₂]:Eu²⁺,
   Ca₈Mg(SiO₄)₄Cl₂:Eu²⁺,
   BaSi₂O₂N₂:Eu²⁺,
   (Ca,Ba,Sr)Si₂O₂N₂:Eu²⁺,
   β-SiAlON:Eu²⁺,
   α-SiAlON:Eu²⁺,
Eu²⁺-doped sulfides, for example:
   CaS:Eu²⁺,
   SrGa₂S₄:Eu²⁺,
   Mn⁴⁰⁺-doped phosphors, wherein a host structure may for example be K₂SiF₆, Na₂SiF₆, K₂TiF₆.

As Mn⁴⁰⁺-doped phosphors fluoride and oxyfluoride phosphors may generally be utilized, for example phosphors of the general formula:

EAₓA_{y}[B_{z}C_{f}D_{g}EₕOₐF_{b}]:Mn⁴⁺C
wherein A is selected from the group consisting of Li, Na, K, Rb, Cs, Cu, Ag, NH₄, or combinations thereof,
wherein EA is selected from the group of elements consisting of Be, Mg, Ca, Ba, Sr, Zn, or combinations thereof,
wherein B is selected from the group of elements consisting of Si, Ge, Sn, Ti, Zr, Hf,
wherein C is selected from the group of elements consisting of Al, Ga, In, Gd, Y, Sc, La, Bi, Cr,
wherein D is selected from the group of elements consisting of Nb, Ta, V, wherein E is selected from the group of elements consisting of W, Mo or combinations thereof;
the partial charge d is derived from [EAₓA_{y}]d from (2*x+y) and is the inverse of the partial charge e of [[B_{z}C_{f}D_{g}EₕOₐF_{b}]:Mn⁴⁺C]ₑ, which is also composed of (4*z+3*f+5*g+6*h+4*c−2*a−b).

Similarly, Mg₄GeO_{3.5}F may be used as the host structure, wherein an activator content is preferably <3 at %, more preferably <1 at %. The additional phosphor may have the general formula of (4−x)MgO*xMgF₂*GeO₂:Mn⁴⁺.

Similarly, Mn⁴⁰⁺-doped A₂Ge₄O₉ and A₃A′Ge₈O₁₈ may be used, wherein A and A′ are each independently selected from the group of elements consisting of Li, K, Na, Rb, as an additional phosphor, for example Mn⁴⁰⁺-doped K₂Ge₄O₉, Rb₂Ge₄O₉ or Li₃RbGe₈O₁₈.

Similarly, Mn⁴⁰⁺-doped Sr₄Al₁₄O₂₅, Mg₂TiO₄, CaZrO₃, Gd₃Ga5O₁₂, Al₂O₃, GdAlO₃LaAlO₃, LiAl₅O₈, SrTiO₃, Y₂Ti₂O₇, Y₂Sn₂O₇, CaAl₁₂O₁₉, MgO, Ba₂LaNbO₆ may be used as an additional phosphor.

According to at least one embodiment, a second or additional phosphor selected from quantum dots comprises a semiconducting material. The semiconducting material may be selected from CdS, CdSe, CdTe, ZnS, ZnTe, HgTe, HgSe, GaP, GaAs, GaSb, AlP, AlAs, AlSb, InP, InAs, InSb, SiC, InN, AlN, and combinations thereof. For example, the quantum dots may comprise a core of the semiconducting material, the core being partially surrounded, preferably completely surrounded, by a shell of an inorganic material,

Alternatively, organic and organic hybrid materials may be used for light conversion (also in combination).

Other nano- and micro-particulate (also amorphous or polycrystalline) compounds may be embedded in the conversion element. They may be used, for example, to adjust the light scattering in the conversion element.

The surface of the conversion element may have an outcoupling structure for improved light outcoupling. The outcoupling structure may be created, for example, by etching, stamping, scribing, laser ablation, etc.

In addition, another phosphor (e.g., in an LED package) may be arranged downstream in the light path for additional conversion. This phosphor preferably absorbs in the range of 400 to 500 nm and emits in the range of 700 to 1500 nm.

In another embodiment, the light emitting device further comprises at least one transparent substrate.

The transparent substrate may be glass, ceramic, plastic, silicone, or sapphire.

The conversion element may be applied to the transparent substrate. For example, the conversion element may be bonded to the transparent substrate.

The conversion element applied to the transparent substrate may subsequently be divided. A plurality of substrates or divided substrates may then be introduced into the light path of a light emitting device (e.g., an LED).

In one embodiment, the light emitting device further comprises at least one light guide.

In another embodiment, the light emitting device further comprises an insulating layer selected from the group consisting of metal oxides, metal nitrides, and combinations thereof.

The conversion element may be coated with the insulating layer, especially as a moisture- and gas-tight encapsulation. For example, the material may be a metal oxide (preferably Al₂O₃, SiO₂, TiO₂, MgO, ZrO₂, ZnO), or a metal nitride (preferably Si₃N₄, AlN, BN) may be used.

The thickness of the insulating layer is preferably in the range of 2 to 500 nm. Particularly preferably, the thickness of the insulating layer is in the range of 15 to 50 nm.

The material of the insulating layer can be deposited by, for example, CVD (chemical vapor deposition), ALD (atomic layer deposition), PECVD (plasma enhanced CVD), PVD (pulsed vapor deposition i.e. sputtering, magnetron sputtering, laser ablation, evaporation, etc.), MOVPE (metalorganic vapor-phase epitaxy), eBeam (electron beam), MBE (molecular beam epitaxy), electrolytic or wet chemical deposition.

In another embodiment, the light emitting device further comprises at least one reflector.

In one embodiment, a light emitting device comprises a radiation emitting semiconductor chip as a light source of a primary radiation. The radiation-emitting semiconductor chip emits electromagnetic radiation of a first wavelength range (primary radiation) from a radiation exit surface. Preferably, the radiation-emitting semiconductor chip emits primary radiation in the wavelength range between 300 nm and 570 nm, preferably in the range 350 nm to 500 nm, more preferably in the range 420 nm to 480 nm.

In one embodiment, the light source may laterally be arranged (orthogonally) to the light emitting surface of the conversion element. In this case, the light-emitting components are installed, for example, in a smartphone or mobile application, where they (optionally) couple into a light guide. For example, this light guide may be a plastic plate. Another backlighting principle is “direct view backlighting”. The exit area in the mobile application may be e.g. 1 mm², preferably it is in the range of 50 μm² to 1 cm².

A number of advantages can be realized using a light emitting device according to the present invention. For applications using a low photon flux, significant reduction in Stokes losses can be realized. Furthermore, adjustability of the final emission wavelength can be achieved via quantum dot quantum confinement (range: e.g. 650 nm to 2 μm or 900 nm to 2 μm by means of, for example, Pb chalcogenides, furthermore in the IR range eventually using Hg chalcogenides). Furthermore, narrow band emission is possible by incorporating monodisperse quantum dots into singlet fission materials. For broadband emission, there is quantum dot multiplexing (i.e., incorporation of quantum dots of different sizes, where the distance between quantum dots must be larger than the FRET radius). In addition, high device efficiency can be achieved by the present invention as a result of photon multiplication.

Furthermore, it is an object of the present invention to use a light emitting device in an infrared emitter or a combined infrared-visible emitter.

It is another object of the present invention to use an optoelectronic semiconductor device in an infrared emitter.

Other advantageous embodiments and further developments of the invention will be apparent from the embodiments described below in connection with the figures.

### FIGURES

Equal elements, elements of the same kind or elements having the same effect are provided with equal reference numbers in the figures. The figures and the proportions of the elements shown in the figures are not to be regarded as being to scale. Rather, some elements, especially layer thicknesses, may be shown exaggeratedly large for better representability and/or understanding.

FIG. 1 shows a light-emitting component according to the invention.

FIG. 2 shows a light-emitting component according to the invention

FIG. 3 shows a light-emitting component according to the invention

FIG. 4 shows a light-emitting component according to the invention

FIG. 5 shows a light-emitting component according to the invention

FIG. 6 shows a light-emitting component according to the invention

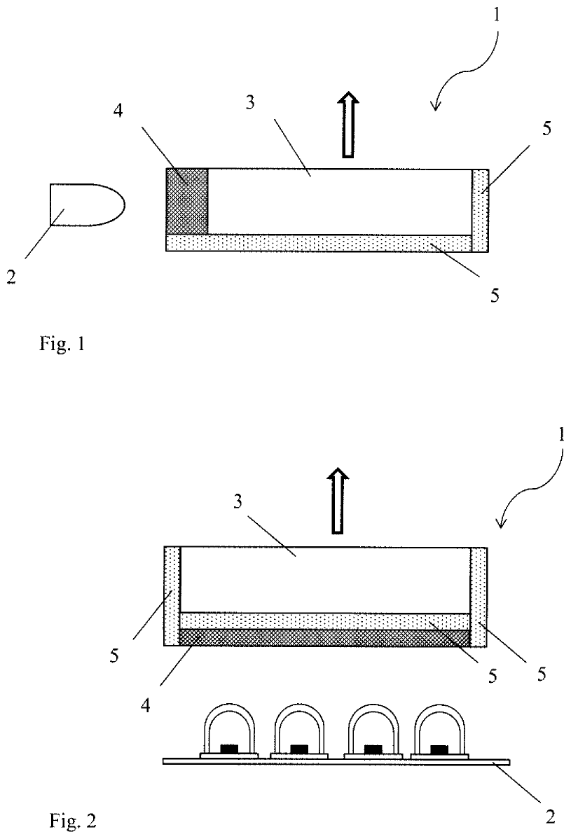

FIG. 1 shows an embodiment of a light-emitting component 1, especially for a so-called edge light {i.e. coupling orthogonal to the light-emitting direction of a light guide) in mobile applications. In this context, FIG. 1 shows a light source 2, a conversion element 3 comprising a first material capable of singlet fission, and quantum dots as a second material. Furthermore, FIG. 1 shows a light guide 4 and a reflector 5. The reflector 5 may be present as a continuous component, or may be present in a plurality of components. In an alternative embodiment (not shown), the light guide 4 and/or the reflector 5 are completely or partially absent. The light extraction direction in FIG. 1 is indicated by the arrow.

FIG. 2 shows an embodiment of a light-emitting component 1, especially for direct lighting (i.e. coupling transversely to the light-emitting direction of a light guide) in a mobile application. In this regard, FIG. 2 shows a plurality of light sources 2, a conversion element 3 comprising a first material capable of singlet fission and quantum dots as a second material. Furthermore, FIG. 2 shows a light guide 4 and a reflector 5. The reflector 5 may be present as one continuous component, or may be present from multiple components. In an alternative embodiment (not shown), the light guide 4 and/or the reflector 5 are not present. In another alternative embodiment (not shown), the light emitting component 1 comprises only one light source 2. The light extraction direction in FIG. 2 is indicated by the arrow.

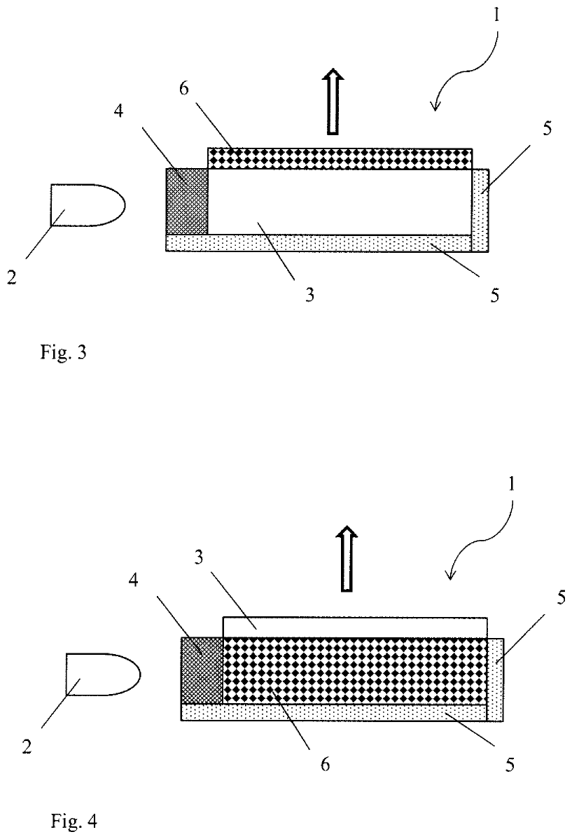

FIG. 3 shows an embodiment of a light-emitting component 1 used, for example, to enable residual light conversion. FIG. 3 shows a light source 2, a conversion element 3 comprising a first material capable of singlet fission and quantum dots as a second material. The light emitting device 1 further comprises a phosphor 6 (inorganic and/or organic) incorporated into a matrix and arranged in close proximity to the conversion element 3. Furthermore, FIG. 3 shows a light guide 4 and a reflector 5. The reflector 5 may be present as a continuous component, or may be present in a plurality of components. In an alternative embodiment (not shown), the light guide 4 and/or the reflector 5 are completely or partially absent. The light extraction direction in FIG. 3 is indicated by the arrow.

FIG. 4 shows another embodiment of a light-emitting component 1, used, for example, to enable residual light conversion. FIG. 4 shows a light source 2, a conversion element 3 comprising a first material capable of singlet fission and quantum dots as a second material. The light emitting device 1 further comprises a phosphor (inorganic and/or organic) incorporated into a matrix and arranged in close proximity to the conversion element 3. Furthermore, FIG. 4 shows a light guide 4 and a reflector 5. The reflector 5 may be present as a continuous component, or may be present in a plurality of components. In an alternative embodiment (not shown), the light guide 4 and/or the reflector 5 are partially or completely absent. The light extraction direction in FIG. 4 is indicated by the arrow.

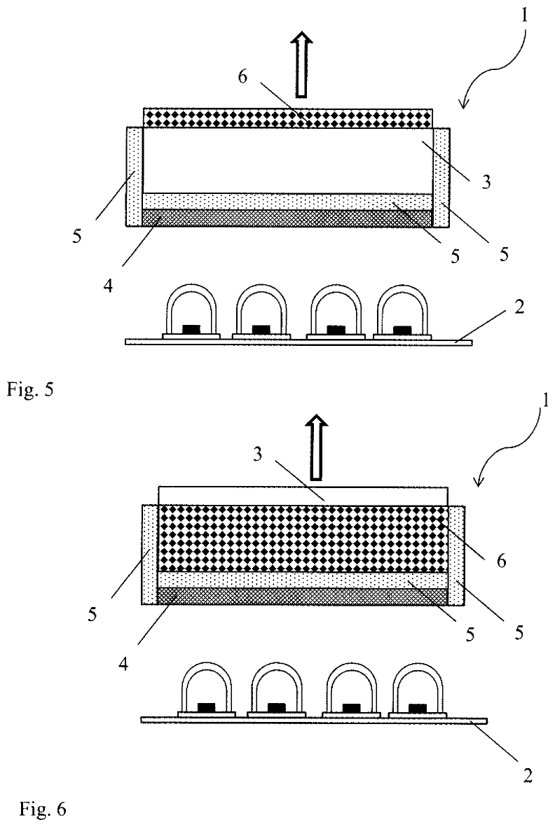

FIG. 5 shows another embodiment of a light-emitting component 1, used, for example, to enable residual light conversion. Herein, FIG. 5 shows a plurality of light sources 2, a conversion element 3 comprising a first material capable of singlet fission and quantum dots as a second material. The light emitting device 1 further comprises a phosphor (inorganic and/or organic) incorporated into a matrix and arranged in close proximity to the conversion element 3. Furthermore, FIG. 5 shows a light guide 4 and a reflector 5. The reflector 5 may be present as a continuous component, or may be present in a plurality of components. In an alternative embodiment (not shown), the light guide 4 and/or the reflector 5 are partially or completely absent. The light extraction direction in FIG. 5 is indicated by the arrow. In another alternative embodiment (not shown), only one light source 2 is present instead of the plurality of light sources 2.

FIG. 6 shows another embodiment of a light-emitting component 1, used, for example, to enable residual light conversion. Herein, FIG. 6 shows a plurality of light sources 2, a conversion element 3 comprising a first material capable of singlet fission and quantum dots as a second material. The light emitting device 1 further comprises a phosphor 6 (inorganic and/or organic) incorporated into a matrix and arranged in close proximity to the conversion element 3. Furthermore, FIG. 5 shows a light guide 4 and a reflector 5. The reflector 5 may be present as a continuous component, or may be present in a plurality of components. In an alternative embodiment (not shown), the light guide 4 and/or the reflector 5 are partially or completely absent. The light extraction direction in FIG. 6 is indicated by the arrow. In another alternative embodiment (not shown) only one light source 2 is present instead of the plurality of light sources 2.

The invention is not limited to the description of the example embodiments. The invention rather encompasses any new feature as well as any combination of features, especially including any combination of features in the patent claims, even when this feature or any combination as such is not explicitly mentioned in the patent claims or embodiments.

This patent application claims the priority of German patent application 102018126355.4, the disclosure of which is hereby incorporated by reference.

### LIST OF REFERENCE NUMBERS

1 light emitting component
2 light source
3 conversion element
4 light guide
5 reflector
6 phosphor

1. A light emitting device (1) comprising:
at least one conversion element (3) comprising:
at least a first material selected from the group consisting of polyacene, rubrene and derivatives thereof;
at least a second material, said second material being a quantum dot; and
at least one light source (2), wherein the at least one light source (2) emits at least one photon in the range of 3.5 eV to 2.5 eV, preferably in the range of 3.0 eV to 2.55 eV.

2. The light-emitting device (1) according to claim 1, wherein the at least one quantum dot comprises a band gap in the range from 650 nm to 2 μm, preferably in the range from 900 nm to 2 μm.

3. The light emitting device (1) according to claim 1 or 2, wherein the at least one quantum dot comprises one or more materials, selected from the group consisting of PbS, HgSe, HgTe, CuInS, CuInSe, CdS, CdSe, CdTe, ZnS, ZnSe, ZnTe, HgTe, HgSe, GaP, GaAs, GaSb, AlP, AlAs, AlSb, InP, InAs, InSb, GaSb, SiC, InN, AlN, GaN, BN, ZnO, MgO, InSnO₂, SnO₂, or combinations thereof.

4. The light emitting device (1) according to one of the preceding claims, further comprising at least one phosphor (6), preferably at least one phosphor (6) selected from the group consisting of Cr³⁺-, Sm³⁺-, Yb³⁺-, Nd³⁺-, Bi²⁺-, Dy³⁺-, Ho³⁺-, Cr⁴⁺-, Ni2+-, Er³⁺-, Tm³⁺-, Ce³⁺-, Eu²⁺-, Yb²⁺-doped phosphors, organic phosphors and hybrid organic phosphors and combinations thereof.

5. The light emitting device (1) according one of the preceding claims, further comprising at least one transparent substrate.

6. The light emitting device (1) according one of the preceding claims, further comprising at least one light guide (4).

7. The light emitting device (1) according one of the preceding claims, further comprising an insulating layer selected from the group consisting of metal oxides, metal nitrides and combinations thereof.

8. The light emitting device (1) according one of the preceding claims, further comprising at least one reflector (5).

9. Use of a light emitting device (1) according one of the preceding claims in an infrared emitter or an infrared-to-visible emitter.
